(19) United States
(12) Patent Application Publication
(10) Pub. No.: US 2012/0066876 A1
(43) Pub. Date: Mar. 22, 2012

(54) CREATING AN IMPROVED PIEZOELECTRIC LAYER FOR TRANSDUCERS

(76) Inventor: James D. Huffman, Pittsford, NY (US)

(21) Appl. No.: 12/883,219

(22) Filed: Sep. 16, 2010

(51) Int. Cl. H01L 41/22

(52) U.S. Cl. 29/25.35

(57) ABSTRACT

A method for forming a transducer, the method includes the steps of providing a substrate; providing a dielectric on the substrate; providing a first piezoelectric layer of the dielectric; providing a metal layer on the first piezoelectric layer; etching the metal layer to form a predetermined pattern having at least two electrodes; providing a second piezoelectric layer on the first piezoelectric layer and the etched metal layer; and etching a portion of the substrate surrounding the transducer to permit the transducer to move in a bender configuration.

### CROSS REFERENCE TO RELATED APPLICATIONS

Reference is made to commonly assigned U.S. patent application Ser. No. ______ (Docket #96277) filed concurrently herewith by James D. Huffman, entitled “A TRANSDUCER HAVING AN IMPROVED ELECTRIC FIELD”, the disclosures of which are herein incorporated by reference.

### FIELD OF THE INVENTION

The present invention generally relates to piezoelectric, micro-electro-mechanical (MEMs) devices. More specifically, it relates to such devices having piezoelectric material that provides both an underlying and overlying piezoelectric material layer for the metal layer for enhancing the electric field.

### BACKGROUND OF THE INVENTION

Currently, piezoelectric d33 interdigitated (IDT) thin film MEMSs devices include a substrate over which a dielectric is disposed. A piezoelectric layer is disposed on the dielectric layer, and a conductive layer is disposed on the piezoelectric layer. The conductive layer is then etched in an interdigitated configuration with two or more electrodes. The piezoelectric and dielectric layers are then etched in a predetermined pattern for forming a MEMs device. The substrate under the MEMs device is then removed to allow for in-plane motion.

This specific thin film device architecture allows for a voltage to be applied between the electrodes, which allows for an electric field across the piezoelectric material. Since the electric field is in the direction of the polarization of the piezoelectric material, this induces a stress in the same direction. The stress along the MEMs device with one or more clamped ends will induce a perpendicular motion along the free end of the MEMs device. This operation can also be used in reverse, whereas any force normal to the free end of the MEMs device will cause a corresponding electric field to be produced between the electrodes, which can be sensed as a voltage between the electrodes.

Referring to FIG. 1, in the prior art planar IDT configuration, the electric field is only effective through the bottom piezoelectric material. Although the current piezoelectric thin film MEMs devices are satisfactory, improvements are always desirable. The present invention addresses this shortcoming by having increased electric field efficiency which corresponds to an improvement in the mechanical efficiency in the MEMs device.

### SUMMARY OF THE INVENTION

The present invention is directed to overcoming one or more of the problems set forth above. Briefly summarized, according to one aspect of the invention, the invention resides in a method for forming a transducer, the method comprising the steps of providing a substrate; providing a dielectric on the substrate;

providing a first piezoelectric layer of the dielectric; providing a metal layer on the first piezoelectric layer; etching the metal layer to form a predetermined pattern having at least two electrodes; providing a second piezoelectric layer on the first piezoelectric layer and the etched metal layer; and etching a portion of the substrate surrounding the transducer to permit the transducer to move in a bender configuration.

These and other objects, features, and advantages of the present invention will become apparent to those skilled in the art upon a reading of the following detailed description when taken in conjunction with the drawings wherein there is shown and described an illustrative embodiment of the invention.

### Advantageous Effect of the Invention

The present invention has the advantage of enhancing the electric field in MEMs devices.

### BRIEF DESCRIPTION OF THE DRAWINGS

While the specification concludes with claims particularly pointing out and distinctly claiming the subject matter of the present invention, it is believed that the invention will be better understood from the following description when taken in conjunction with the accompanying drawings, wherein:

FIG. 1 is a cross section of a prior art transducer;

FIG. 2 shows a simplified block schematic diagram of an example embodiment of a printer system made in accordance with the present invention;

FIG. 3 is a schematic view of an example embodiment of a continuous printhead made in accordance with the present invention;

FIG. 4 is a schematic view of a simplified gas flow deflection mechanism of the present invention;

FIGS. 5-13 are cross sectional drawings of the transducer of the present invention illustrating the method for making the transducer;

FIG. 14 is perspective drawing of the transducer of the present invention illustrating one embodiment;

FIG. 15 is perspective drawing of the transducer of the present invention illustrating an alternative embodiment;

FIG. 16 is perspective drawing of the transducer of the present invention illustrating a third embodiment; and

FIG. 17 is a cross section of a transducer of the present invention illustrating improved electric field efficiency.

### DETAILED DESCRIPTION OF THE INVENTION

The present description will be directed in particular to elements forming part of, or cooperating more directly with, apparatus in accordance with the present invention. It is to be understood that elements not specifically shown or described may take various forms well known to those skilled in the art. In the following description and drawings, identical reference numerals have been used, where possible, to designate identical elements.

The example embodiments of the present invention are illustrated schematically and not to scale for the sake of clarity. One of the ordinary skills in the art will be able to readily determine the specific size and interconnections of the elements of the example embodiments of the present invention.

As described herein, the example embodiments of the present invention provide a printhead or printhead components typically used in inkjet printing systems. However, many other applications are emerging which use inkjet printheads to emit liquids (other than inks) that need to be finely metered and deposited with high spatial precision. As such, as described herein, the terms “liquid” and “ink” refer to any material that can be ejected by the printhead or printhead components described below.

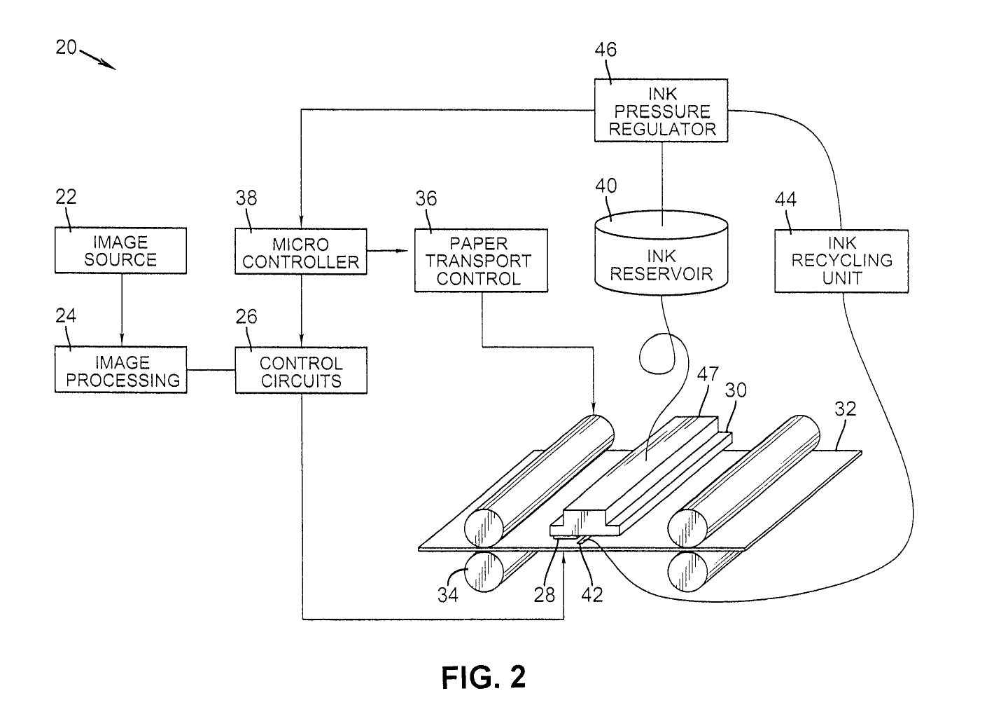

The preferred embodiment illustrates the present invention in a continuous inkjet printer although the present invention is also useful with a drop on demand inkjet printer. Referring to FIG. 2, a continuous inkjet printer system 20 includes an image source 22 such as a scanner or computer which provides raster image data, outline image data in the form of a page description language, or other forms of digital image data. This image data is converted to half-toned bitmap image data by an image processing unit 24 which also stores the image data in memory. A plurality of drop forming mechanism control circuits 26 read data from the image memory and applies time-varying electrical pulses to a drop forming mechanism(s) 28 that are associated with one or more nozzles of a printhead 30. These pulses are applied at an appropriate time, and to the appropriate nozzle, so that drops formed from a continuous ink jet stream will form spots on a recording medium 32 in the appropriate position designated by the data in the image memory.

Recording medium 32 is moved relative to printhead 30 by a recording medium transport system 34, which is electronically controlled by a recording medium transport control system 36, and which in turn is controlled by a micro-controller 38. The recording medium transport system shown in FIG. 2 is a schematic only, and many different mechanical configurations are possible. For example, a transfer roller could be used as recording medium transport system 34 to facilitate transfer of the ink drops to recording medium 32. Such transfer roller technology is well known in the art. In the case of page width printheads, it is most convenient to move recording medium 32 past a stationary printhead. However, in the case of scanning print systems, it is usually most convenient to move the printhead along one axis (the sub-scanning direction) and the recording medium along an orthogonal axis (the main scanning direction) in a relative raster motion.

Ink is contained in an ink reservoir 40 under pressure. In the non-printing state, continuous ink jet drop streams are unable to reach recording medium 32 due to an ink catcher 42 that blocks the stream and which may allow a portion of the ink to be recycled by an ink recycling unit 44. The ink recycling unit reconditions the ink and feeds it back to reservoir 40. Such ink recycling units are well known in the art. The ink pressure suitable for optimal operation will depend on a number of factors, including geometry and thermal properties of the nozzles and thermal properties of the ink. A constant ink pressure can be achieved by applying pressure to ink reservoir 40 under the control of ink pressure regulator 46.

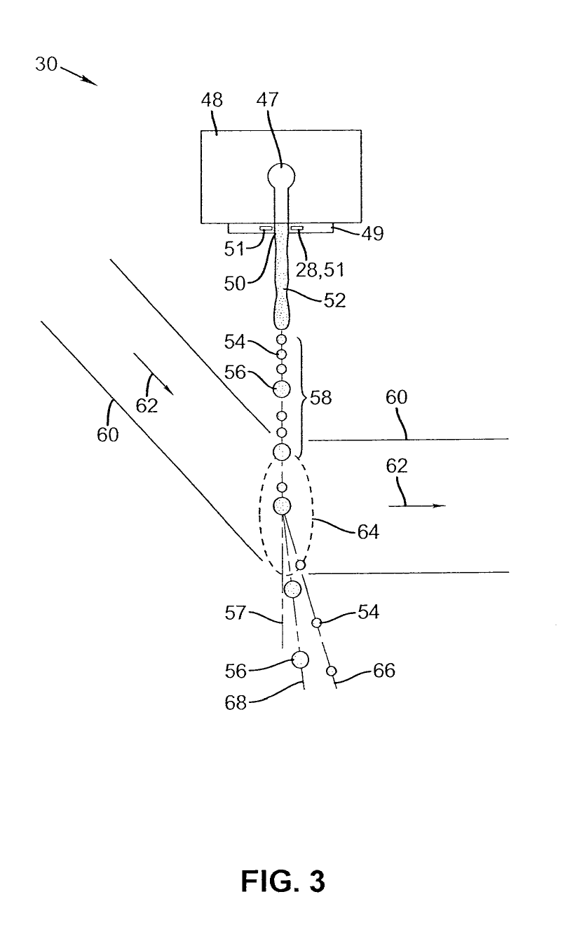

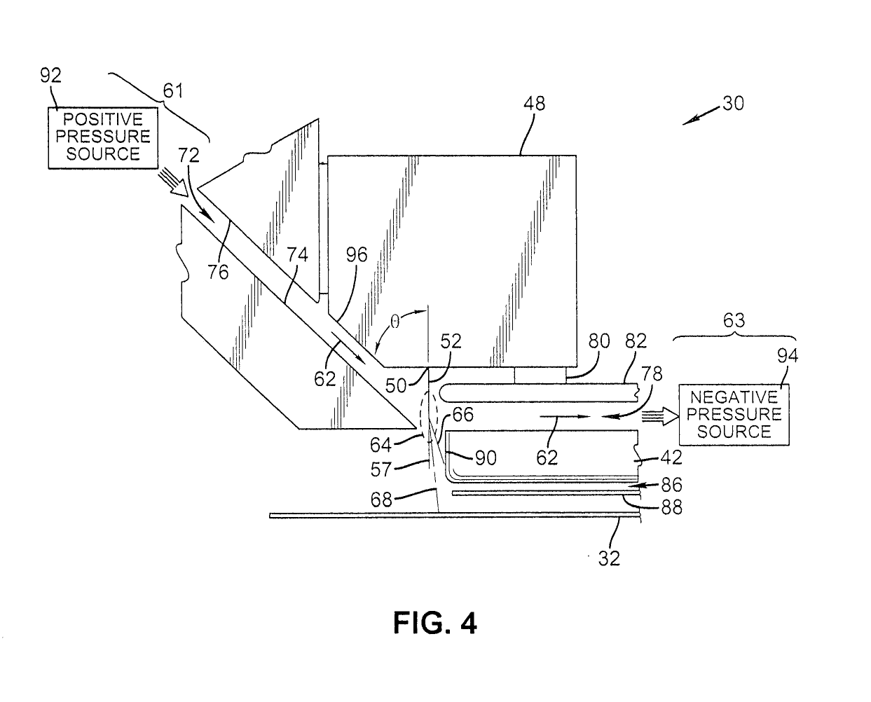

The ink is distributed to printhead 30 through an ink channel 47. The ink preferably flows through slots or holes etched through a silicon substrate of printhead 30 to its front surface, where a plurality of nozzles and drop forming mechanisms, for example, MEMS piezoelectric transducers, are situated. When printhead 30 is fabricated from silicon, drop forming mechanism control circuits 26 can be integrated with the printhead. Printhead 30 also includes a deflection mechanism (not shown in FIG. 2) which is described in more detail below with reference to FIGS. 3 and 4.

Referring to FIG. 3, a schematic view of a continuous liquid printhead 30 is shown. A jetting module 48 of printhead 30 includes an array or a plurality of nozzles 50 formed in a nozzle plate 49. In FIG. 3, nozzle plate 49 is affixed to jetting module 48. However, if preferred, nozzle plate 49 can be integrally formed with jetting module 48.

Liquid, for example, ink, is emitted under pressure through each nozzle 50 of the array to form filaments of liquid 52. In FIG. 3, the array or plurality of nozzles extends into and out of the figure and preferably the nozzle array is a linear array of nozzles.

Jetting module 48 is operable to form liquid drops having a first size and liquid drops having a second size through each nozzle. To accomplish this, jetting module 48 includes a drop stimulation or drop forming device or transducer 28 (see FIG. 2), for example, MEMS piezoelectric transducer or a MEMS actuator, that, when selectively activated, perturbs each filament of liquid 52, for example, ink, to induce portions of each filament to break off from the filament and coalesce to form drops 54, 56.

In FIG. 3, drop forming device 28 is a piezoelectric transducer 51 located in a nozzle plate 49 on one or both sides of nozzle 50. Typically, one drop forming device 28 is associated with each nozzle 50 of the nozzle array. However, a drop forming device 28 can be associated with groups of nozzles 50 or all of nozzles 50 of the nozzle array.

When printhead 30 is in operation, drops 54, 56 are typically created in a plurality of sizes, for example, in the form of large drops 56, a first size, and small drops 54, a second size. The ratio of the mass of the large drops 56 to the mass of the small drops 54 is typically approximately an integer between 2 and 10. A drop stream 58 including drops 54, 56 follows a drop path or trajectory 57.

Printhead 30 also includes a gas flow deflection mechanism 60 that directs a flow of gas 62, for example, air, past a portion of the drop trajectory 57. This portion of the drop trajectory is called the deflection zone 64. As the flow of gas 62 interacts with drops 54, 56 in deflection zone 64 it alters the drop trajectories. As the drop trajectories pass out of the deflection zone 64 they are traveling at an angle, called a deflection angle, relative to the un-deflected drop trajectory 57.

Small drops 54 are more affected by the flow of gas than are large drops 56 so that the small drop trajectory 66 diverges from the large drop trajectory 68. That is, the deflection angle for small drops 54 is larger than for large drops 56. The flow of gas 62 provides sufficient drop deflection and therefore sufficient divergence of the small and large drop trajectories so that catcher 42 (shown in FIG. 4) can be positioned to intercept the small drop trajectory 66 so that drops following this trajectory are collected by catcher 42 while drops following the other trajectory bypass the catcher and impinge a recording medium 32 (shown in FIG. 4).

When catcher 42 is positioned to intercept small drop trajectory 66, large drops 56 are deflected sufficiently to avoid contact with catcher 42 and strike the print media. When catcher 42 is positioned to intercept small drop trajectory 66, large drops 56 are the drops that print, and this is referred to as large drop print mode.

Jetting module 48 includes an array or a plurality of nozzles 50. Liquid, for example, ink, supplied through channel 47, is emitted under pressure through each nozzle 50 of the array to form filaments of liquid 52. In FIG. 3, the array or plurality of nozzles 50 extends into and out of the figure.

Drop stimulation or drop forming device 28 (shown in FIGS. 2 and 3) associated with jetting module 48 is selectively actuated to perturb the filament of liquid 52 to induce portions of the filament to break off from the filament to form drops. In this way, drops are selectively created in the form of large drops and small drops that travel toward a recording medium 32.

Referring to FIGS. 3 and 4, positive pressure gas flow structure 61 of gas flow deflection mechanism 60 is located on a first side of drop trajectory 57. Positive pressure gas flow structure 61 includes first gas flow duct 72 that includes a lower wall 74 and an upper wall 76. Gas flow duct 72 directs gas flow 62 supplied from a positive pressure source 92 at downward angle θ of approximately a 45° relative to liquid filament 52 toward drop deflection zone 64 (also shown in FIG. 2). An optional seal(s) 80 provides an air seal between jetting module 48 and upper wall 76 of gas flow duct 72.

Upper wall 76 of gas flow duct 72 does not need to extend to drop deflection zone 64 (as shown in FIG. 4). In FIG. 4, upper wall 76 ends at a wall 96 of jetting module 48. Wall 96 of jetting module 48 serves as a portion of upper wall 76 ending at drop deflection zone 64.

Negative pressure gas flow structure 63 of gas flow deflection mechanism 60 is located on a second side of drop trajectory 57. Negative pressure gas flow structure includes a second gas flow duct 78 located between catcher 42 and an upper wall 82 that exhausts gas flow from deflection zone 64. Second duct 78 is connected to a negative pressure source 94 that is used to help remove gas flowing through second duct 78. An optional seal(s) 80 provides an air seal between jetting module 48 and upper wall 82.

As shown in FIG. 4, gas flow deflection mechanism 60 includes positive pressure source 92 and negative pressure source 94. However, depending on the specific application contemplated, gas flow deflection mechanism 60 can include only one of positive pressure source 92 and negative pressure source 94.

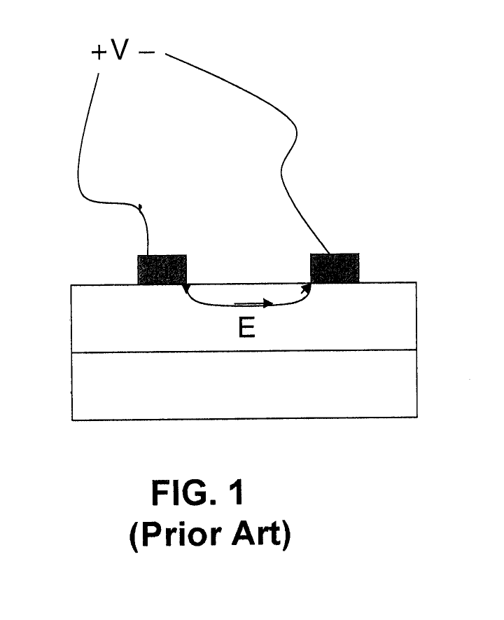

Gas supplied by first gas flow duct 72 is directed into the drop deflection zone 64, where it causes large drops 56 to follow large drop trajectory 68 and small drops 54 to follow small drop trajectory 66. As shown in FIG. 4, small drop trajectory 66 is intercepted by a front face 90 of catcher 42. Small drops 54 contact face 90 and flow down face 90 and into a liquid return duct 86 located or formed between catcher 42 and a plate 88. Collected liquid is either recycled and returned to ink reservoir 40 (shown in FIG. 1) for reuse or discarded. Large drops 56 bypass catcher 42 and travel on to recording medium 32. Alternatively, catcher 42 can be positioned to intercept large drop trajectory 68. Large drops 56 contact catcher 42 and flow into a liquid return duct located or formed in catcher 42. Collected liquid is either recycled for reuse or discarded. Small drops 54 bypass catcher 42 and travel on to recording medium 32.

As shown in FIG. 4, catcher 42 is a type of catcher commonly referred to as a “Coanda” catcher. However, the “knife edge” catcher shown in FIG. 2 and the “Coanda” catcher shown in FIG. 4 are interchangeable and work equally well. Alternatively, catcher 42 can be of any suitable design including, but not limited to, a porous face catcher, a delimited edge catcher, or combinations of any of those described above.

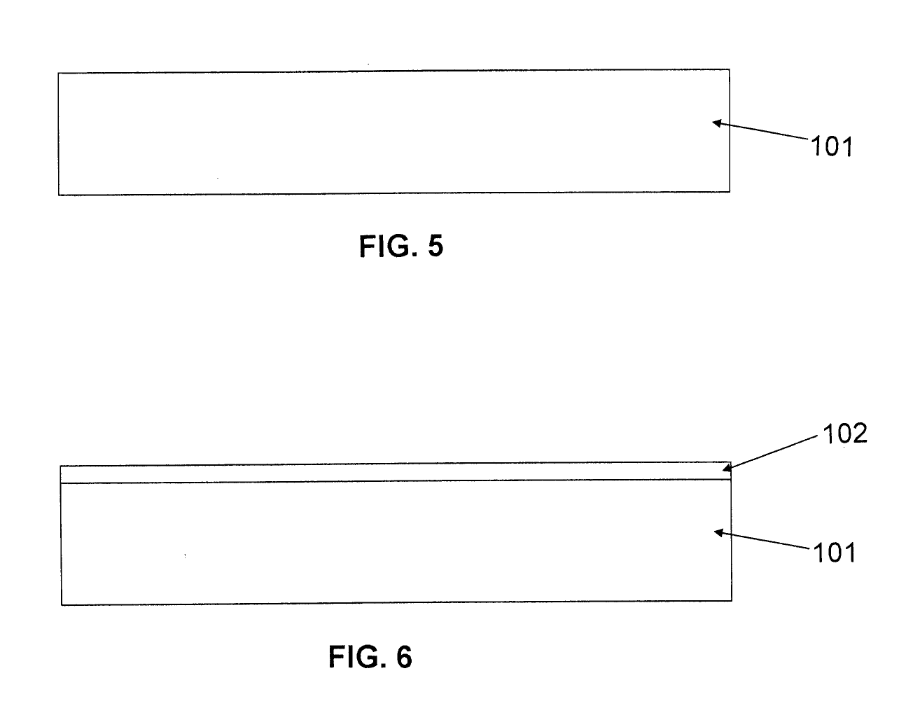

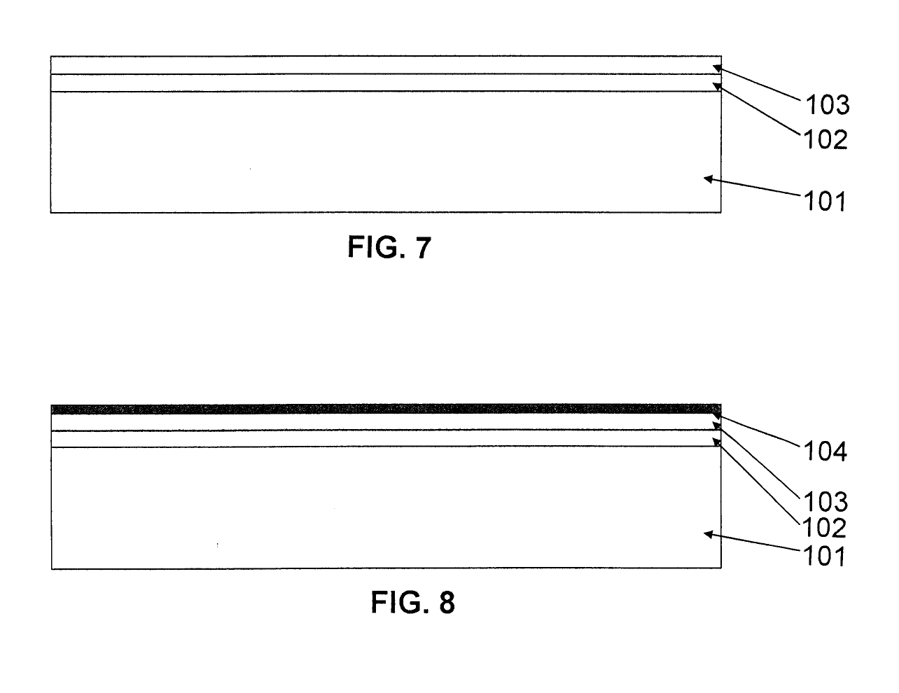

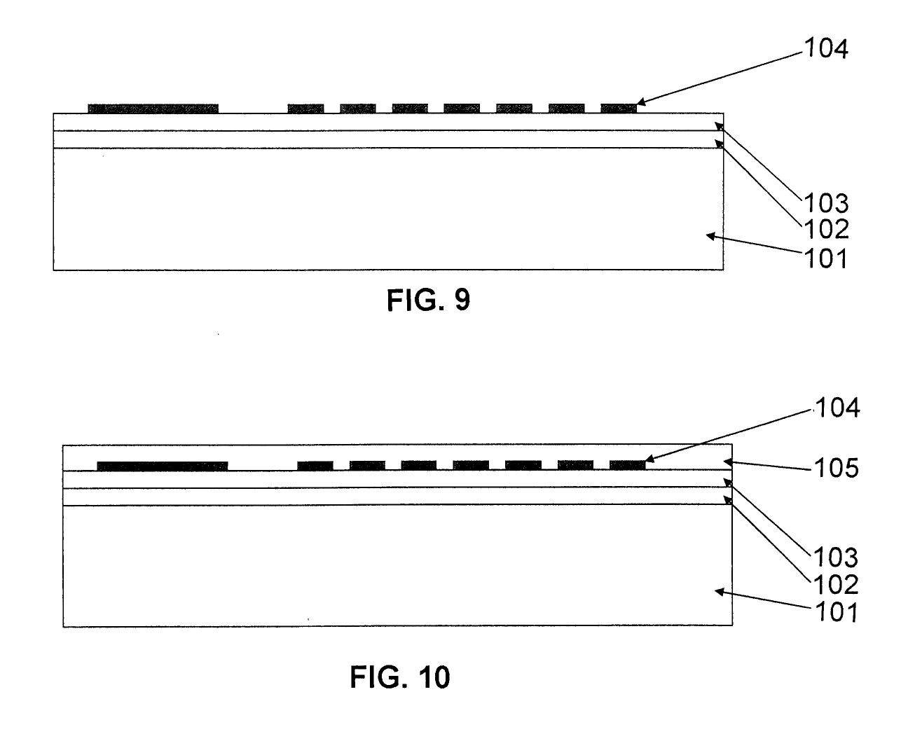

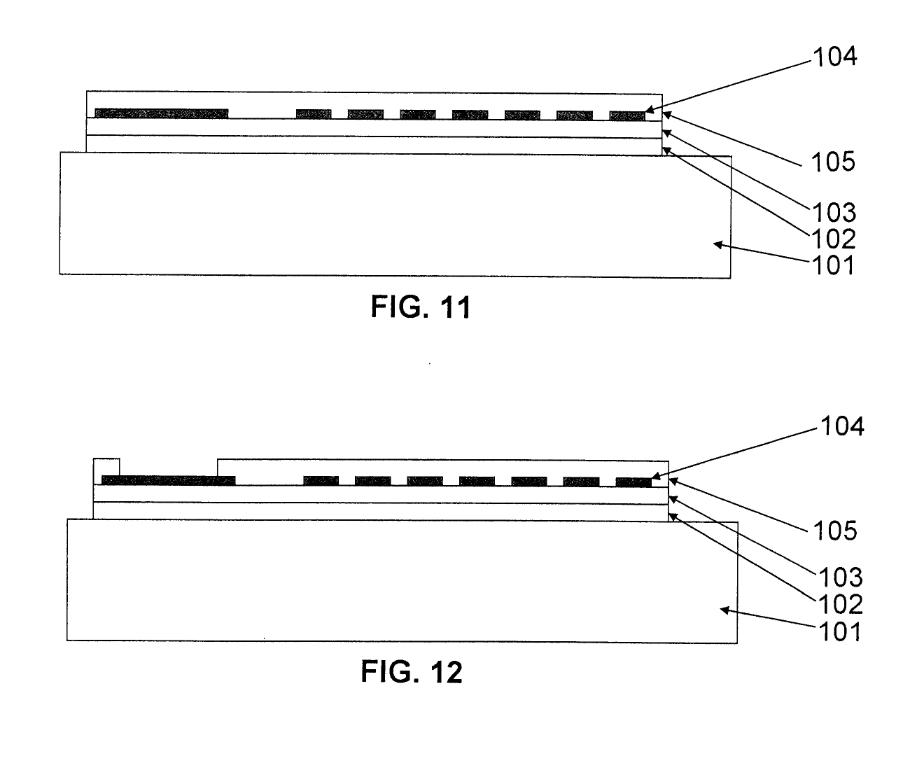

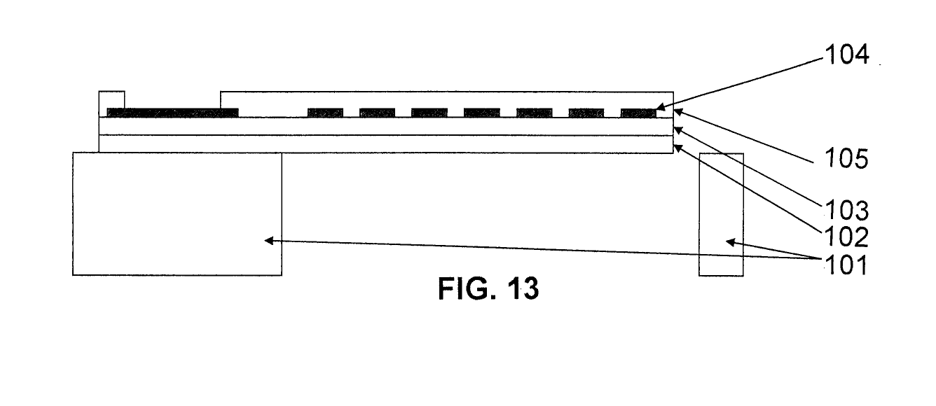

Referring to FIGS. 5-13, the following description and associated drawings will first describe the method of forming the piezoelectric transducer 51 of the present invention. In this regard and turning now to FIGS. 5 through 13, first a substrate 101 is provided and a dielectric material 102 is deposited on the substrate. Next, a first piezoelectric layer 103 is deposited on the dielectric layer 102 and an electrode metal layer 104 is deposited on the first piezoelectric layer 103. The metal is then patterned etched to remove portions of the metal layer 104 to form the desired pattern. The pattern may be, but is not limited to, an interdigitated pattern, a pattern of concentric metal circles (rings) or the like. The particular pattern varies according to the particular need. A second layer 105 of piezoelectric material is deposited onto the first piezoelectric layer 103 and surrounding and covering the patterned metal layer 104.

The first piezoelectric 103 and second layers 105 and dielectric 102 are patterned etched to remove portions of each of these etched layers 102, 103 and 105. The second piezoelectric layer 105 is patterned etched to expose a portion of the metal layer 104 in order to permit electrical contact from system electronics to the electrode. Finally, the substrate 101 is pattern etched in the desired pattern to remove a portion of the substrate 101 so that a portion of the MEMs transducer is free to move.

The dielectric layer 102, metal layer 104 and first 103 and second 105 piezoelectric layer is illustrated as deposited, these steps may also be individually or in any combination be vacuum deposited, deposited in solution or laminated. Still further the metal layer is preferably platinum, and the piezoelectric layer is preferably lead zirconium titanate.

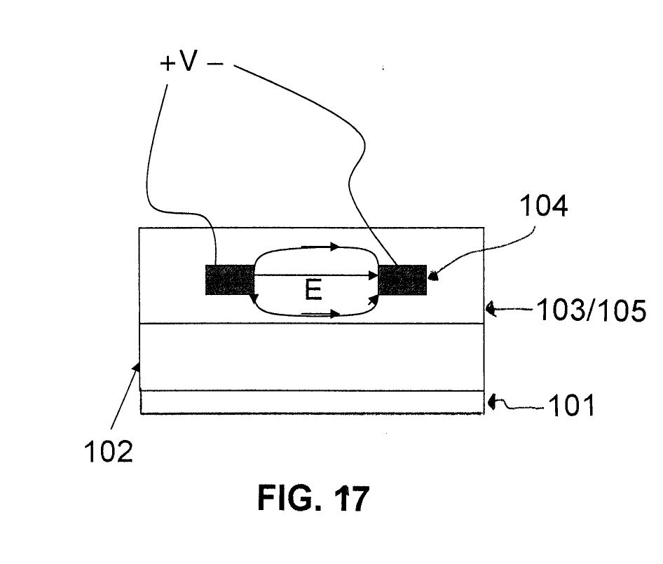

Although the two piezoelectric layers 103 and 105 are created in two separate steps, when the transducer is finally made, the two piezoelectric layers 103 and 105 are, in essence, a piezoelectric layer that forms a single, uniform layer that is an underlying, between and overlying layer for at least a portion of the metal layer. In other words, the piezoelectric layer substantially surrounds or entirely surrounds the metal layer except for the electrode which has no overlying layer for at least a portion of it. The configuration of the present invention permits enhanced electrical fields over the planar interdigitated architecture since there is more piezoelectric material between the electrodes for the electric field, as shown in FIG. 17.

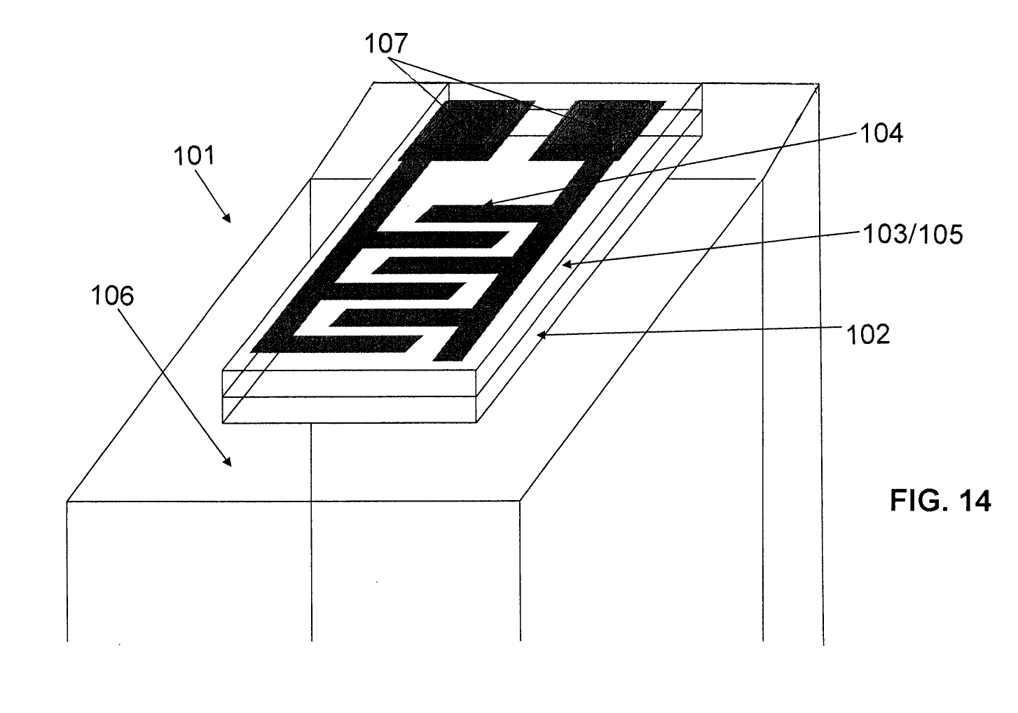

Referring to FIG. 14, there is shown one embodiment of the transducer of the present invention. In this embodiment, the substrate 101 is etched so that one end of the transducer does not have an underlying layer of substrate (i.e., includes an empty space) 106 so that this end spanning the open space 106 freely moves when in operation. The metal layer 104 is configured in an interdigitated pattern and two electrodes 107 are exposed so that external electrical connections can be made thereto for providing a mechanism (typically a voltage) for controlling operation of the transducer. This configuration is commonly referred to as a free standing cantilever.

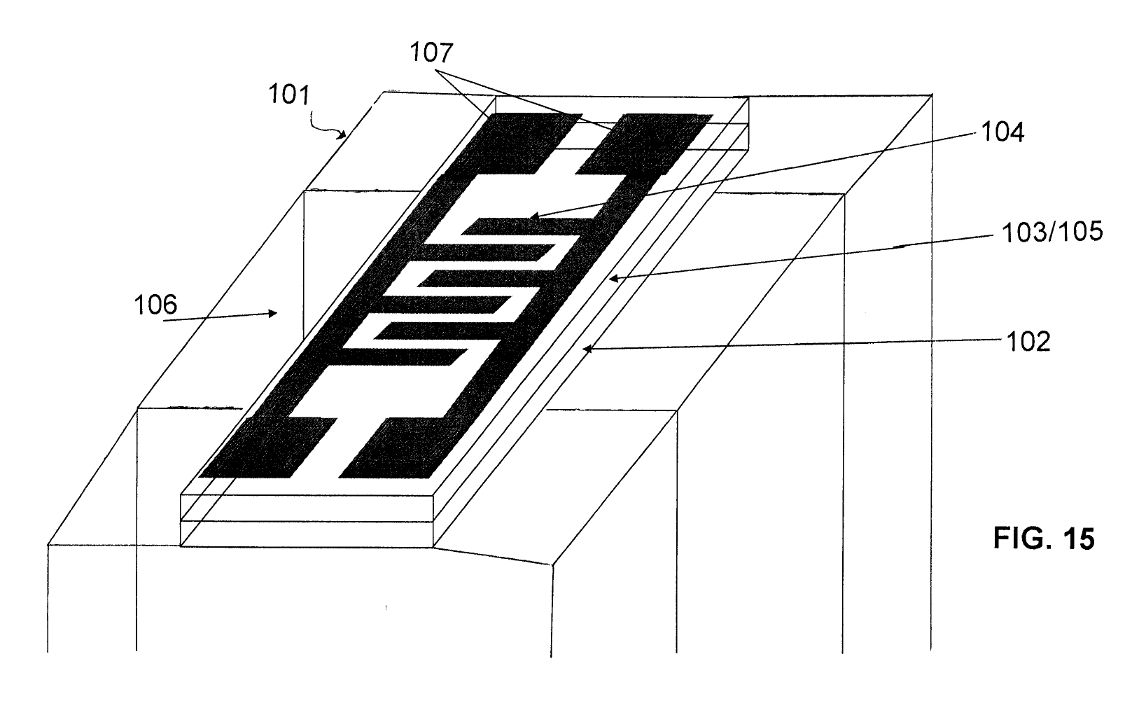

Referring to FIG. 15, the transducer includes two fixed ends. In this embodiment, there is no substrate 101 underlying in the middle portion of the substrate (i.e., includes an empty space) 106 so that the middle portion of the transducer spanning the open space 106 freely moves when in operation. As in the previous embodiment, two electrodes 107 are exposed for permitting connection to external device for controlling operation of the transducer. This configuration is commonly referred to as the clamped-clamped beam.

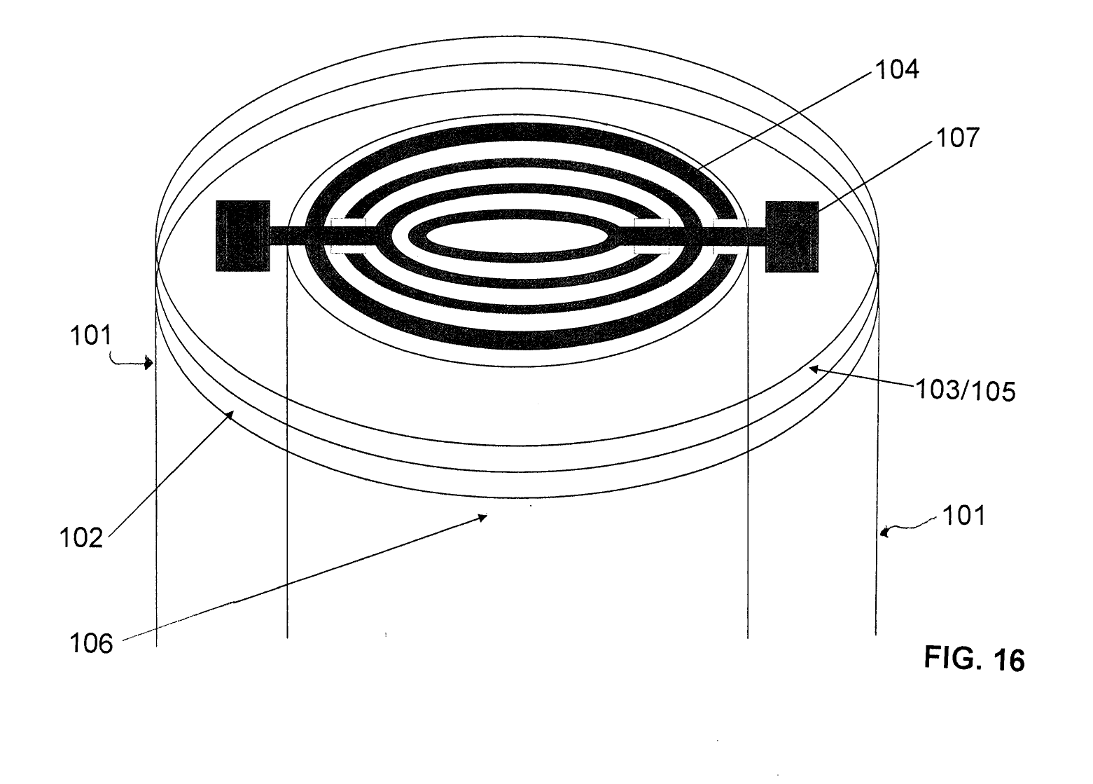

Referring to FIG. 16, there is shown a third embodiment of the present invention. In this embodiment, the metal layer 104 is formed in a plurality of concentric circles having two electrodes 107. Each electrode 107 is electrically connected to one or more of the circular metallic layers 104. The particular connection is depended upon the particular need as those skilled in the art can determine. It is noted that there is substrate beneath and spanning the periphery of the transducer and there is no substrate beneath and spanning the middle portion beneath the concentric rings (i.e., includes an empty space) 106 so that this portion of the transducer spanning the open space 106 moves freely. This configuration forms a free standing membrane. As in the other embodiment, the electrodes 107 are left exposed so that external electrical connections can be made thereto for means for controlling operation of the transducer.

Referring to FIG. 17, there is shown a cross section of the transducer of the present invention. As compared to the prior of FIG. 1, the present invention provides an improvement by depositing an additional piezoelectric layer 105 on the etched conductive layer. This acts to improve the efficiency of the electric field between the electrodes, which allows for more efficient mechanical operation of the MEMs device. In the prior art of FIG. 1, the electric field is only effective through the bottom piezoelectric material. In contrast, in the present invention of FIG. 17, the electric field is effective through the bottom piezoelectric material, the piezoelectric material between the conductors, and the top piezoelectric material. This electric field efficiency improvement in the embedded IDT configuration corresponds to an improvement in the mechanical efficiency in the MEMs device.

The invention has been described in detail with particular reference to certain preferred embodiments thereof, but it will be understood that variations and modifications can be effected within the spirit and scope of the invention.

### PARTS LIST

20 inkjet printer system
22 image source
24 processing unit
26 control circuits
28 drop forming mechanisms
30 printhead
32 recording medium
34 recording medium transport system
36 recording medium transport control system
38 micro-controller
40 ink reservoir
42 ink catcher
44 ink recycling unit
46 ink pressure regulator
47 ink channel
48 jetting module
49 nozzle plate
50 nozzles
51 piezoelectric transducer
52 liquid
54 drops
56 drops
57 trajectory
58 drop stream
60 gas deflector
61 positive pressure gas flow structure
62 gas
63 negative pressure gas flow structure
64 deflection zone
66 small drop trajectory
68 large drop trajectory
72 first gas flow duct
74 lower wall
76 upper wall
78 second gas flow duct
80 seal
82 upper wall
86 liquid duct return
88 plate
90 front face
92 positive pressure source
94 negative pressure source
96 wall
101 substrate
102 dielectric
103 first piezoelectric layer
104 metal layer
105 second piezoelectric layer
106 empty space
107 electrode

1. A method for forming a transducer, the method comprising the steps of:
(a) providing a substrate;
(b) providing a dielectric on the substrate;
(c) providing a first piezoelectric layer of the dielectric;
(d) providing a metal layer on the first piezoelectric layer;
(e) etching the metal layer to form a predetermined pattern having at least two electrodes;
(f) providing a second piezoelectric layer on the first piezoelectric layer and the etched metal layer; and
(g) etching a portion of the substrate surrounding the transducer to permit the transducer to move in a bender configuration.

2. The method as in claim 1 further comprising the step of (g) etching the dielectric layer, first piezoelectric layer and the second piezoelectric layer to form the transducer.

3. The method as in claim 1 further comprising the step of removing at least a portion of the second piezoelectric layer to form an electrode.

4. The method as in claim 1, wherein steps (b), (c), (d) and (f) may be individually or in any combination be vacuum deposited, deposited in solution or laminated.
